(19) United States
(12) Patent Application Publication
(10) Pub. No.: US 2005/0278593 A1
(43) Pub. Date: Dec. 15, 2005

(54) Scan-test structure having increased effectiveness and related systems and methods

(76) Inventors: Fidel Muradali, Mountian View, CA (US); Ismed D.S. Hartanto, Castro Valley, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/865,057

(22) Filed: Jun. 9, 2004

(51) Int. Cl. G01R 31/28

(52) U.S. Cl. 714/724

(57) ABSTRACT

An integrated circuit comprises an input node operable to receive test data. First circuitry configurable as a first delay circuit is coupled to the node, operable to generate a first test signal by delaying the test data a first delay time and operable to generate a second test signal by delaying the test data a second delay time. Second circuitry configurable as a first scan chain is coupled to the first delay circuit and is operable to receive the first test signal. Third circuitry configurable as a second scan chain is coupled to the first delay circuit and is operable to receive the second test signal.

### BACKGROUND

Integrated circuits are presently tested using a number of structured design-for-testability (DFT) techniques. These techniques are based on the general concept of making all or some state variables (e.g., memory elements like flip-flops and latches) directly controllable and observable. If this can be arranged, a circuit can be treated, as far as testing of combinational faults is concerned, as a combinational network.

An often-used DFT methodology is based on scan chains. This methodology assumes that during testing, at least some memory elements are interconnected to form one or more shift registers. Specifically, a circuit that has been designed for test has two modes of operation: a normal mode and a test or scan mode. In the normal mode, the memory elements perform their regular functions. In the scan mode, the memory elements become scan cells that are connected to form a number of shift registers called scan chains. These scan chains are used to shift a set of test patterns into the circuit and to shift out a set of response patterns. The test response patterns are then compared to respective predetermined fault-free response patterns to determine if the circuit under test is working properly.

As illustrated in FIG. 1, a typical integrated circuit 10 in test mode includes a plurality of scan chains 20, each of which receives test data through a corresponding input pin 30 and provides response data through a corresponding output pin 40. Consequently, each scan chain 20 requires two chip pins, an input pin 30 and an output pin 40. Unfortunately, as the density of integrated circuits increases, the number of scan chains requiring testing may exceed the number of pins that an integrated circuit of given size may support.

FIG. 2 illustrates a prior-art solution to this problem, in which the scan chains 20 of an integrated circuit 10 are arranged in parallel to form test-chain bundles 50, each bundle requiring only one corresponding input pin 30 and one corresponding output pin 40. A compactor 60 is provided at the output of each scan-chain bundle 50, and serves to compact the data output by each scan chain of the bundle 50 into a single bit stream bit for transmission via the output pin 40.

Referring to FIG. 3, the scan chains 20 that compose the bundle 50 are logically aligned such that logically aligned scan-chain segments form groups 70 of aligned scan-chain segments. For example, the segments of a group 70 may be interconnected and may interact with one another while processing data (such as scan-test data represented by the binary values “0” and “1” in each of the scan chains illustrated in FIG. 3) such that the data input to one scan-chain segment in the group 70 may depend on the data output by another scan-chain segment in the group 70. The result of this arrangement is that test-vector data input to each scan chain 20 is typically correlated due to each scan chain receiving the same test vector at the same time. This correlated test-vector arrangement allows testing of only about 90% of testable errors.

One technique for testing for the remaining 10% of possible errors is to reconfigure the scan chains 20 so that they are serially interconnected instead of bundled in parallel. Although this uncorrelates the scan chains 20, it requires at least one additional test pattern to be input to the integrated circuit 10. And because the scan chains 20 are now serially coupled, this additional test pattern is longer than the test patterns used for the scan chain bundles 50.

All of the test patterns used to test an IC are typically stored in the memory of an IC tester (not shown). As the density of ICs increases, the sizes of the test patterns may also increase. If the test patterns grow to the point where they can no longer fit into the tester's memory, then one must either upgrade the tester with a larger memory, or buy a new tester having a larger memory. Unfortunately, upgrading tester memory or purchasing a new tester is often expensive. And in the case of a new tester, the training of the operator(s) to run the new tester is often time consuming and expensive.

Accordingly, a technique for providing uncorrelated data to a scan-chain bundle would be an advancement in the art.

### SUMMARY

According to an embodiment of the present invention, an integrated circuit comprises an input node operable to receive test data. First circuitry configurable as a first delay circuit is coupled to the node, operable to generate a first test signal by delaying the test data a first delay time and operable to generate a second test signal by delaying the test data a second delay time. Second circuitry configurable as a first scan chain is coupled to the first delay circuit and is operable to receive the first test signal. Third circuitry configurable as a second scan chain is coupled to the first delay circuit and is operable to receive the second test signal.

### BRIEF DESCRIPTION OF THE DRAWINGS

FIG. 1 is a schematic diagram of a conventional integrated circuit as configured in a scan-chain test mode;

FIG. 2 is a schematic diagram of a conventional integrated circuit in test mode employing scan-chain bundling;

FIG. 3 is a schematic diagram of a conventional scan-chain bundle receiving a test vector;

FIG. 4A is a schematic diagram of an integrated circuit that includes a scan-chain bundle according to an embodiment of the present invention;

FIG. 4b is a logical diagram of the integrated circuit of FIG. 4A;

FIG. 5 is a detailed schematic diagram of a delay circuit of FIGS. 4A and 4B according to an embodiment of the invention;

FIG. 6 is a schematic diagram of an integrated circuit that includes a scan-chain bundle according to an alternative embodiment of the invention;

FIG. 7 is a schematic diagram of an integrated-circuit testing device and an integrated circuit under test according to an embodiment of the present invention; and

FIG. 8 is a schematic diagram of an integrated circuit testing device and IC under test according to an alternative embodiment of the present invention.

### DETAILED DESCRIPTION

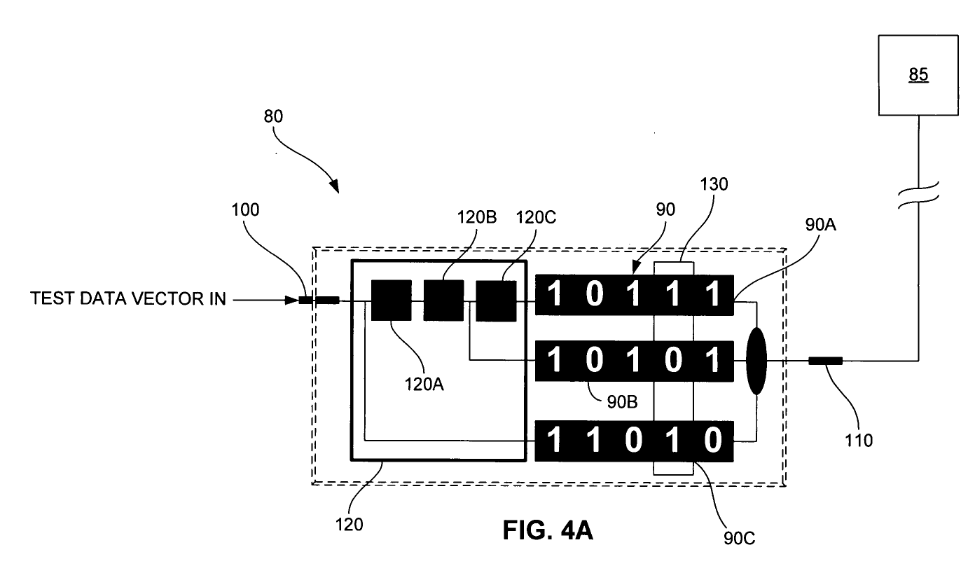

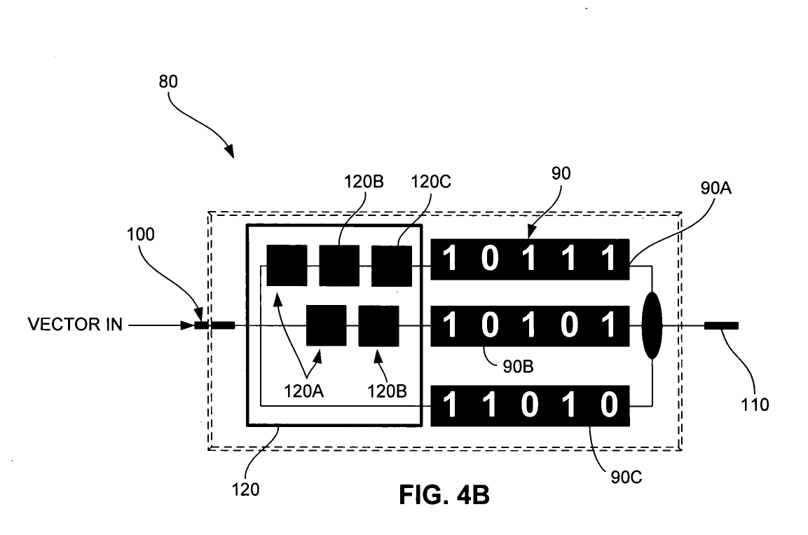

FIG. 4A is a schematic illustration of an exemplary portion of an integrated circuit 80 in a test mode according to an embodiment of the present invention. The integrated circuit 80 includes a test chain bundle 90 coupled to a single input pin 100 and a single output pin 110. A delay circuit 120 is interposed in series with and between the input pin 100 and an input node of each scan chain 90A, 90B, and 90C of the scan-chain bundle 90. The delay circuit 120 comprises a series of digital delay elements 120A, 120B, and 120C, each of which imposes a transmission delay, equal to a predetermined number of clock cycles, on the test-data vector that the input pin 100 receives.

In operation, the delay circuit 120 receives the test-data vector via the input pin 100. As can be seen in both FIG. 4A and the logical illustration of integrated circuit 80 shown in FIG. 4B, the scan chain 90C receives the test-data vector with no delay. The scan chain 90B receives the test-data vector only after delay elements 120A and 120B have imposed respective delays on the test-data vector. Similarly, the scan chain 90A receives the test-data vector only after delay elements 120A, 120B, and 120C have imposed respective delays on the test-data vector. By imposing delays of varying length on receipt of the test-data vector by the scan chains in the bundle 90, data passing through the bundle 90 is uncorrelated (as illustrated in exemplary group 130).

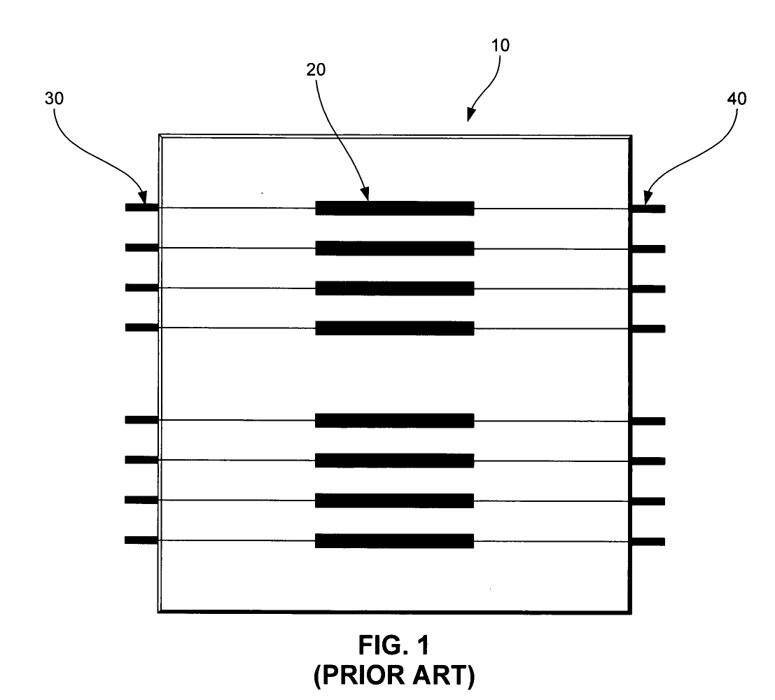

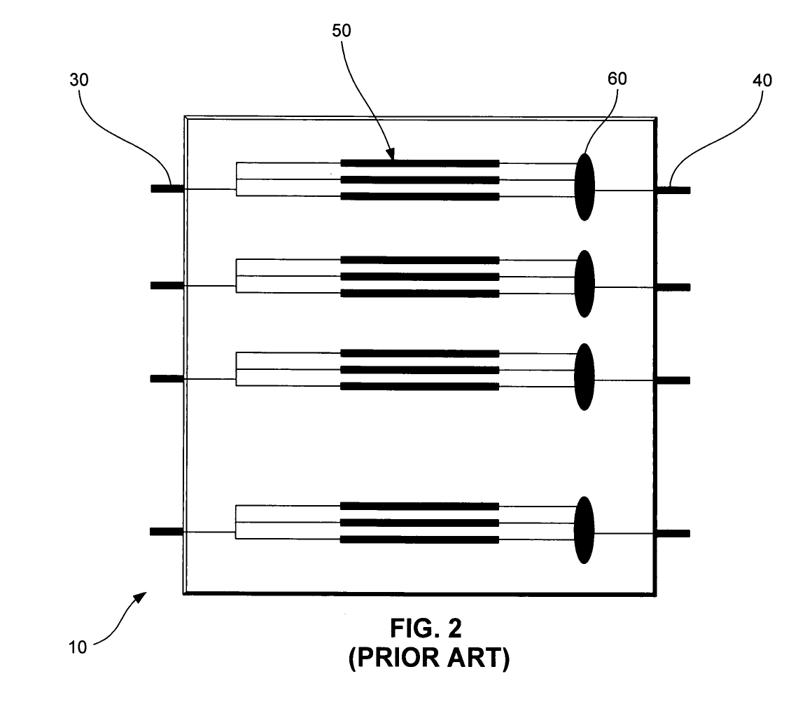

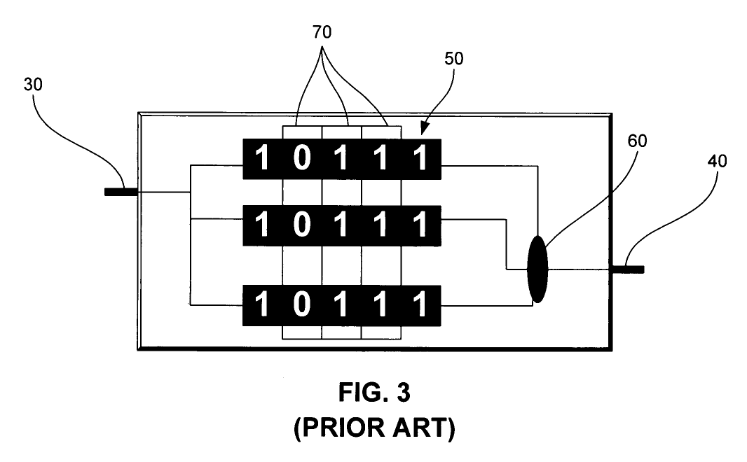

By using the circuit 120 to uncorrelate the test data vector among the scan chains 90A-90C of the bundle 90, one can typically test for over 90%, and often 100%, of the possible errors without recoupling the scan chains in series. Consequently, this reduces the number of required test vectors, and thus the amount of test data that the IC tester (not shown FIGS. 4A and 4B) must store. Therefore, the tester often stores less test data for the IC 80 than it does for a conventional IC (such as the IC 108 of FIGS. 1-3) having a comparable density and number of pins.

Furthermore, still referring to FIGS. 4A and 4B, the inclusion of three delay elements 120A, 120B, and 120C in the illustrated topology is for exemplary purposes only. Any practicable number of delay elements may be included in such a delay circuit and connected to the scan chains 90A, 90B, and 90C in any practicable topology. Also, the bundle 90 may include more or fewer than three scan chains.

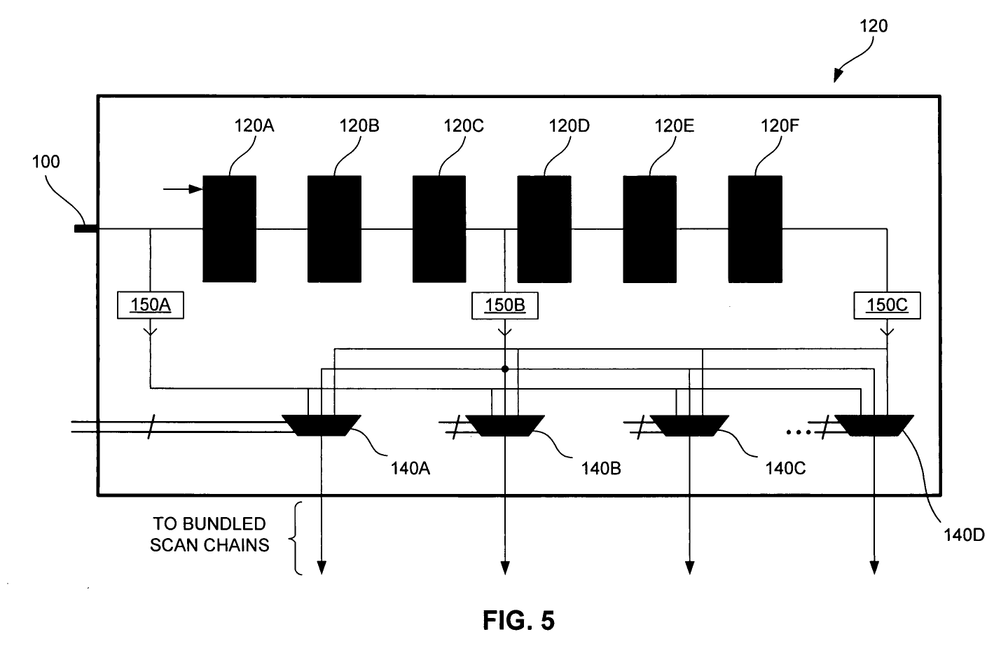

FIG. 5 is a detailed schematic illustration of the delay circuit 120 of FIGS. 4A and 4B according to an embodiment of the invention. The delay circuit 120 comprises six delay elements 120A-120F. The input pin 100 and the delay elements 120C and 120F are coupled to delay-selection multiplexers 140A-140D and to optional synchronizing elements 150A-150C. The integrated circuit of which the delay circuit 120 is a part comprises a clock (not shown) that clocks the delay elements 120A-120F and the multiplexers 140A-140D. The tester (not shown) may have a different clock. Therefore, the synchronizing elements 150A-150C synchronize the test-vector data from the tester to the scan chains 90A-90C (FIGS. 4A and 4B). If the tester and IC 80 (FIGS. 4A and 4B) are clocked with the same signal, then the elements 150A-150C may be omitted.

In operation, and as similarly described above with reference to FIGS. 4A and 4B, the delay circuit 120 receives a test-data vector via the input pin 100. A predetermined number of delay units as imposed by each of delay elements 120A-120F may be applied to the test-data vector. In the example illustrated in FIG. 5, there are three pre-selected delays: zero units, three delay units, as represented by the delay elements 120A-120C, and six delay units as represented by delay elements 120A-120F. The multiplexers 140A-140D, each correspond to a particular scan chain of a scan chain bundle (not shown), thereby allowing adjustable selection of the amount of delay, if any, received by a particular scan chain. Accordingly, the test-data vector, once received by the delay circuit 120 at input pin 100, is transmitted with no delay to a predetermined one of the multiplexers 140A-140D, where the test-data vector is then relayed to a first scan chain 90C (FIGS. 4A-4B) of the bundle. The test-data vector, once received by delay circuit 120 at input pin 100, is also routed through at least a portion of delay elements 120A-120F. At the conclusion of the pre-selected three-unit delay, the test-data vector is routed through synchronization element 150A to a predetermined one of the multiplexers 140A-140D, where the test-data vector is then relayed to a second scan chain 90B of the bundle. Finally, at the conclusion of the pre-selected six-unit delay, the test-data vector is routed through synchronization element 150B to a predetermined one of the multiplexers 140A-140D, where the test-data vector is then relayed to a third scan 90A chain of the bundle. Consequently, the first, second, and third scan chains 90A-90C receive uncorrelated versions of the same test vector.

It is important to note that the connections illustrated in FIG. 5 between or among delay elements 120A-120F and the multiplexers 140A-140D are for illustrative purposes only. That is, more than the three delay periods illustrated in FIG. 5 may be imposed upon the test-data vector prior to its receipt by corresponding bundled scan chains. Additionally, each element 120 may impose a delay (e.g., in clock cycles) different than that of each of the other elements 120.

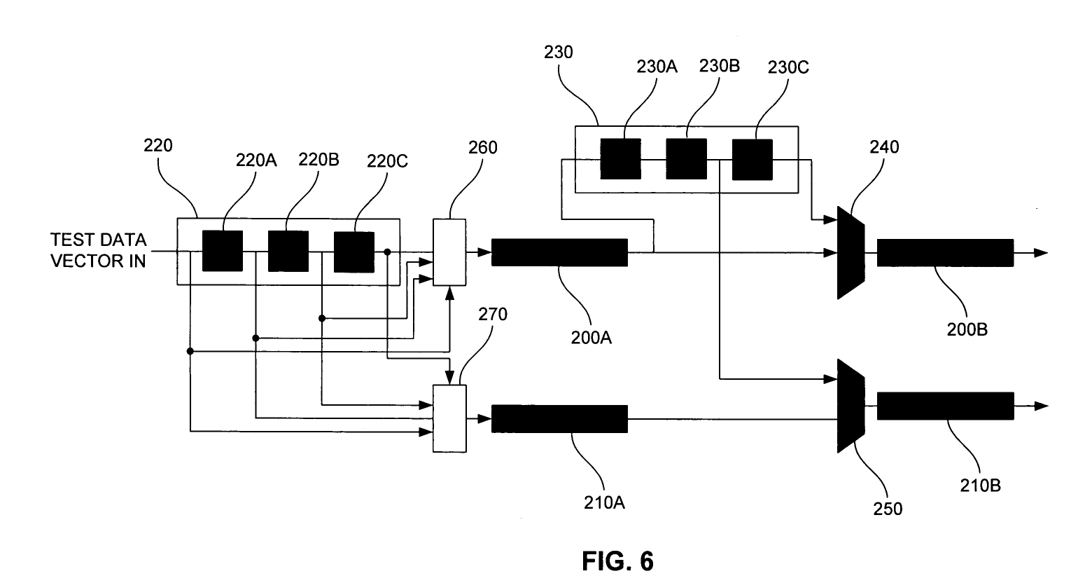

FIG. 6 is a schematic illustration of the integrated circuit 80 according to an alternative embodiment of the present invention. In this embodiment, two scan chains 200 and 210 have each been separated into two respective segments, 200A, 200B and 210A, 210 B. Accordingly, in addition to a first delay circuit 220 at the inputs of scan chain segments 200A and 210A, a second delay circuit 230 may be interposed between the outputs of scan chain segments 200A and 210A, and the inputs of the scan chain segments 200B and 210B, respectively. Each of delay circuits 220 and 230 have corresponding delay elements 220A-220C and 230A-230C operating in a manner similar to delay elements described above with reference to FIGS. 4A, 4B and 5. Furthermore, optional multiplexers 260 and 270 may be included to allow selection of the delay for each scan-chain segment.

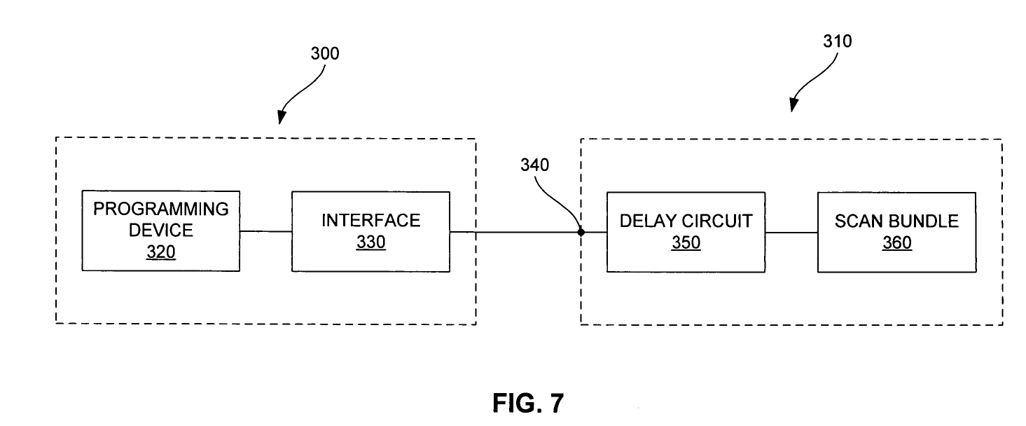

FIG. 7 is a schematic illustration of an integrated circuit testing device 300 and an IC 310 under test according an embodiment of the present invention. The testing device 300 comprises an interface 330 that functions to transmit a test-data vector and other signals to an input node 340 of an integrated circuit 310. The testing device 300 further comprises a programming device 320 coupled to the interface 330. The programming device generates and transmits test data to a programmable delay circuit 350, which couples the data to at least one scan chain bundle 360. The programmable delay circuit 350 is similar in structure and function to the delay circuit 120 of FIG. 5, and may be distributed among scan-chain segments like the delay circuits 220 and 230 of FIG. 6. Before transmitting the test data, a signal transmitted from the programming device 320 serves to configure the multiplexers 140 (FIG. 5) of the delay circuit 350 so as to allow the programming device to select the input delay for each of the scan chains 360.

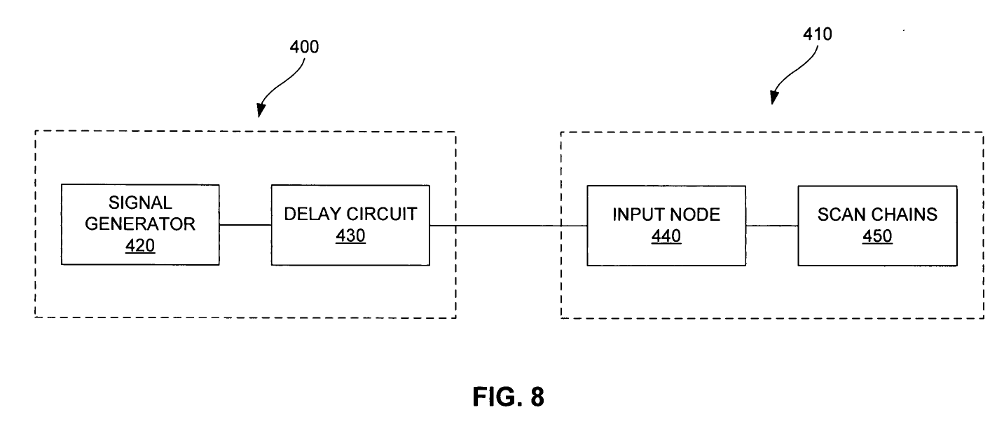

FIG. 8 is a schematic illustration of an alternative embodiment of an integrated circuit testing device 400 according to principles of the present invention. The testing device 400 comprises a test-signal generator 420 functioning to generate test-data vectors. The testing device 400 further comprises a delay circuit 430 coupled to the signal generator 420. The delay circuit 430, in an embodiment, is similar in structure and function to the delay circuit 120 illustrated in FIG. 5. The delay circuit 430 is configured to interface with an input node 440 of an integrated circuit 410. The input node 440 is coupled to a plurality of scan chains 450 of the integrated circuit 410. In operation, the delay circuit 430 receives a test-data vector from the generator 420. The delay circuit 430 transmits an undelayed test-data vector to the input node 440 for transmission to a first of the scan chains 450. Subsequently, and after delaying the test-data vector in a manner similar to that described hereinabove, the delay circuit 430 transmits a delayed test-data vector to the input node 440 for transmission to a second of the scan chains 450.

After passing the above-described tests, the integrated circuit 80 may be a component of an electronic system, such as a computer system, having a power supply unit 85 (FIG. 4A) to which the integrated circuit 80 may be coupled in a conventional manner.

The preceding discussion is presented to enable a person skilled in the art to make and use the invention. Various modifications to the disclosed embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

1. An integrated circuit, comprising:
an input node operable to receive test data;
first circuitry configurable as a first delay circuit that is coupled to the node, operable to generate a first test signal by delaying the test data a first delay time, and operable to generate a second test signal by delaying the test data a second delay time;
second circuitry configurable as a first scan chain that is coupled to the first delay circuit and is operable to receive the first test signal; and
third circuitry configurable as a second scan chain that is coupled to the first delay circuit and is operable to receive the second test signal.

2. The integrated circuit of claim 1 wherein:
the first circuitry is operable to generate a third test signal by delaying the test data a third delay time; and
the integrated circuit further comprises fourth circuitry configurable as a third scan chain that is coupled to the first delay circuit and is operable to receive the third test signal.

3. The integrated circuit of claim 1 wherein the first delay circuit further comprises at least one delay element configurable to set the duration of the first delay time.

4. The integrated circuit of claim 1 wherein the first delay circuit further comprises at least one multiplexer configurable to provide the first test signal to the third circuitry and the second test signal to the second circuitry.

5. The integrated circuit of claim 4 wherein the at least one multiplexer is programmable.

6. The integrated circuit of claim 1 wherein the first circuitry further comprises at least one synchronizer operable to synchronize the test data with a clock.

7. The integrated circuit of claim 1, further comprising:
fourth circuitry configurable as a second delay circuit that is coupled to at least one of the second and third circuitry, operable to generate a third test signal by delaying the test data a third delay time; and
fifth circuitry configurable as a third scan chain that is coupled to the second delay circuit and is operable to receive the third test signal.

8. The integrated circuit of claim 1, further comprising an output node operable to receive test data propagated through the first and second scan chains; and
wherein the input node comprises a pin.

9. The integrated circuit of claim 1, further comprising first and second output nodes operable to receive test data propagated through the first and second scan chains; and
wherein the input node comprises a pin.

10. The integrated circuit of claim 1, further comprising a logic circuit coupled to the first and second scan chains and generating a serial data stream; and
wherein the input node comprises a pin.

11. A testing system, comprising:
an interface operable to provide test data to an input node of an integrated circuit; and
a programmer operable to program first circuitry of the integrated circuit to generate a first test signal by delaying the test data a first delay time, and to generate a second test signal by delaying the test data a second delay time, the programmer further operable to configure second circuitry of the integrated circuit as a first scan chain to receive the first test signal, and to configure third circuitry of the integrated circuit as a second scan chain to receive the second test signal.

12. A method, comprising:
generating a first test signal by delaying test data a first delay time;
generating a second test signal by delaying the test data a second delay time;
providing the first test signal to a first scan chain; and
providing the second test signal to a second scan chain.

13. The method of claim 12 wherein:
generating the first and second test signals comprises configuring first circuitry as a delay circuit;
providing the first test signal comprises configuring second circuitry as the first scan chain; and
providing the second test signal comprises configuring third circuitry as the second scan chain.

14. The method of claim 13 wherein a tester configures the first, second and third circuitry.
